(19) United States
(12) Patent Application Publication
(10) Pub. No.: US 2025/0392111 A1
(43) Pub. Date: Dec. 25, 2025

(54) DYNAMIC OVERCURRENT THRESHOLD

(71) Applicant: Texas Instruments Incorporated, Dallas, TX (US)

(72) Inventors: Pourya Assem, DALLAS, TX (US); Timothy Merkin, PRINCETON, TX (US); Kannan Krishna, DALLAS, TX (US); Tranber Liao, SHANGHAI (CN)

(73) Assignee: Texas Instruments Incorporated, Dallas, TX (US)

(21) Appl. No.: 18/750,438

(22) Filed: Jun. 21, 2024

(51) Int. Cl. H02H 3/08; H03F 1/02; H04R 3/00

(52) U.S. Cl. CPC H02H 3/08; H03F 1/0261; H04R 3/007

(57) ABSTRACT

In one example, an apparatus comprises an amplifier, a power stage, and an overcurrent protection circuit. The amplifier has an amplifier input and an amplifier output. The power stage has a power stage input and a power stage output, the power stage input coupled to the amplifier output. The overcurrent protection circuit is coupled to the power stage, the overcurrent protection circuit having an overcurrent threshold control input coupled to the amplifier.

### CROSS-REFERENCE TO RELATED APPLICATIONS

The present application is related to: (a) U.S. application Ser. No. 18/385,848, entitled “METHODS AND APPARATUS TO MODULATE SIGNALS USING MULTI-CLASS MODULATION CIRCUITRY”, Attorney Docket Number T103189US01, filed on Oct. 31, 2023; (b) U.S. application Ser. No. 17/402,264, entitled “METHODS AND APPARATUS TO GENERATE A MODULATION PROTOCOL TO OUTPUT AUDIO”, Attorney Docket Number T100439US01, filed on Aug. 13, 2021; and (c) U.S. application Ser. No. 17/491,133, entitled “SWITCHING AMPLIFIER HAVING LINEAR TRANSITION TOTEM POLE MODULATION”, Attorney Docket Number T100752US01, filed on Sep. 30, 2021, which are hereby incorporated by reference in their entireties.

### BACKGROUND

A system may include overcurrent protection circuitry to improve safety and reliability. For example, a system may include a power stage to drive a load. The power stage may include one or more transistors. The overcurrent protection circuitry can sense an amount of current conducted by the transistors of the power stage. If the current exceeds a threshold, the overcurrent protection circuitry may disable the transistors, or otherwise disconnect the transistors from the power supply, to prevent the excessive current from damaging the transistors and/or overheating the system. While the overcurrent protection circuitry can improve safety and reliability, false triggering of the overcurrent protection circuitry can also disrupt the normal operation of the system, especially for an audio system that is intended to drive the load continuously.

### SUMMARY

In one example, an apparatus comprises an amplifier, a power stage, and an overcurrent protection circuit. The amplifier has an amplifier input and an amplifier output. The power stage has a power stage input and a power stage output, the power stage input coupled to the amplifier output. The overcurrent protection circuit is coupled to the power stage, the overcurrent protection circuit having an overcurrent threshold control input coupled to the amplifier.

In one example, an apparatus comprises an amplifier, a first power stage, a second power stage, an overcurrent protection circuit, and a modulator. The amplifier has an amplifier input and an amplifier output. The first power stage has a first power stage input and a first power stage output, the first power stage input coupled to the amplifier output. The overcurrent protection circuit is coupled to the first power stage, the overcurrent protection circuit having an overcurrent threshold control input coupled to the amplifier. The modulator has a modulator input and a modulator output, the modulator input coupled to the amplifier input. The second power stage has a second power stage input and a second power stage output, the second power stage input coupled to the modulator output.

In one example, a method comprises providing a first signal to a power stage. The method further comprises obtaining a second signal indicative of a slew rate at an output of the power stage, and setting an overcurrent threshold of the power stage responsive to the slew rate.

### BRIEF DESCRIPTION OF THE DRAWINGS

FIGS. 1A and 1B are schematics illustrating examples of an audio system.

FIGS. 2 and 3 are schematics illustrating additional examples of the audio system of FIGS. 1A and 1B.

FIG. 4 is a schematic illustrating an example of a power stage and an overcurrent protection circuit that can be part of the audio system of FIGS. 1A-3.

FIGS. 5A and 5B include graphs illustrating examples of operations of the power stage and the overcurrent protection circuits of FIG. 4.

FIG. 6 is a schematic illustrating an example of a power stage, and overcurrent protection circuit, and an overcurrent threshold generation circuit.

FIG. 7 is a schematic illustrating examples of internal components of the overcurrent threshold generation circuit of FIG. 6.

FIG. 8, FIG. 9, and FIG. 10 are schematics illustrating examples of internal components of the overcurrent threshold generation circuit of FIGS. 6 and 7.

FIG. 11 illustrates another example of an overcurrent threshold generation circuit.

FIG. 12A and FIG. 12B include graphs illustrating examples of operations of the overcurrent threshold generation circuit of FIGS. 6-11.

FIG. 13 is a flowchart illustrating examples of setting an overcurrent threshold.

### DETAILED DESCRIPTION

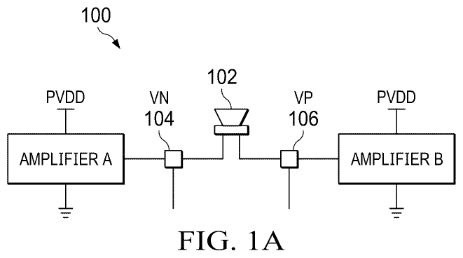

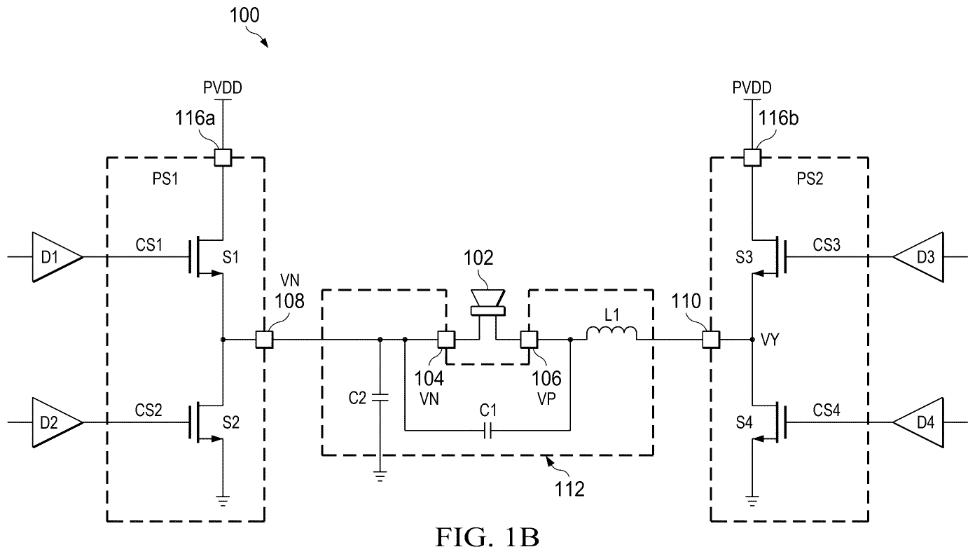

FIG. 1A illustrates an example audio system 100. As shown, system 100 includes a first amplifier (labelled amplifier A) and a second amplifier (labelled amplifier B) driving speaker 102. Amplifier A can be coupled to terminal 104 of speaker 102, and amplifier B can be coupled to terminal 106 of speaker 102. Amplifiers A and B can be of different types with different control schemes. For example, amplifier A can be of a non-switching type, and amplifier B can be of a switching type.

A switching amplifier includes a power stage that generates a multilevel signal (e.g., a binary signal, a trilevel signal, etc.) by selectively connecting the power stage output to one of multiple voltage sources. In some examples, a switching amplifier may operate as a class D amplifier. The switching amplifier may be driven by a modulating circuit that receives a sinusoidal audio signal and generates pulse width modulated (PWM) signals, pulse density signals, and/or any other type of modulated control signals to control the power stage to also generate a modulated signal having discrete signal levels (e.g., binary, ternary, etc.). The modulated signal provided by the power stage can have a timing property, such as duty cycle, pulse width, etc., modulated/varied to reflect an instantaneous amplitude of the audio signal. The modulated signal generated by the power stage can be filtered (e.g., by a low pass filter, or by the inductance of a speaker) to generate an amplified version of the sinusoidal audio signal, and the amplified sinusoidal audio signal can be fed to the speaker. The low pass filter may include an LC filter including a series inductor coupled between the output of the switching amplifier and the speaker, and a shunt capacitor coupled between the speaker and the ground. The low pass filter may also include a capacitor coupled across terminals of the speaker.

A non-switching amplifier may include another power stage driven by a control circuit including a linear amplifier. The control circuit can receive a sinusoidal audio signal, and provide control signals having magnitudes that varies (e.g., linearly or closed to be linearly) according to an instantaneous magnitude of the audio signal to the non-switching amplifier. Responsive to the control signals, the non-switching amplifier can also generate an analog signal having a magnitude that can track the audio signal when the non-switching amplifier operates in a linear mode where the analog signal voltage level is below the supply voltage of the power stage. In a case where the analog signal voltage level is above the supply voltage, the non-switching amplifier may operate in a saturation mode where the analog signal is clipped and limited at the supply voltage. In some examples, the non-switching amplifier may operate as a class A amplifier, a class B amplifier, a class AB amplifier, etc. The output of the non-switching amplifier can also be filtered (e.g., by another low pass filter) to attenuate high frequency components (e.g., noise) and distortions caused by, for example, saturation/clipping, non-linear effects such as distortions at conduction angle hand-over, etc. But because the signal output by the non-switching amplifier is in analog and continuous form, the low pass filter can have fewer components. For example, instead of an LC filter, an audio system can include a capacitor at the non-switching amplifier output to perform the filtering.

FIG. 1B illustrates examples of internal components of system 100 of FIG. 1A. The system 100 of FIG. 1B includes a first power stage PS1 having a first output terminal 108, and a second power stage PS2 having a second output terminal 110. First power stage PS1 can represent (or can be part of) amplifier A of FIG. 1A, and second power stage PS2 can represent (or can be part of) amplifier B of FIG. 1A. The first output terminal 108 and the second output terminal 110 are coupled to a LC filter circuit 112. Two speaker terminals 104 and 106 (also described with respect to FIG. 1A) of the LC filter circuit 112 are coupled to the speaker 102.

The power stage PS1 comprises a first transistor S1 and a second transistor S2 coupled in series between a power terminal 116a (e.g., receiving a power supply PVDD) and a ground terminal. For example, a first current terminal of the transistor S1 is coupled to the power terminal 116a, and a second current terminal of the transistor S1 is coupled to the output terminal 108. A first current terminal of the transistor S2 is coupled to the output terminal 108, and a second current terminal of the transistor S2 is coupled to the ground terminal.

The transistor S1 further includes a control terminal coupled to a first power stage input that receives a control signal CS1 from a driver D1, and the transistor S2 includes a control terminal coupled to a second power stage input that receives a control signal CS2 from another driver D2. The transistors S1 and S2 can set the VN voltage at output terminal 108 of the power stage PS1 responsive to control signals CS1 and CS2. In FIG. 1B, power stage PS1 can be controlled as a non-switching amplifier (e.g., class AB, class A, etc.), where CS1 and CS2 can each have a magnitude that varies (e.g., linearly or closed to be linearly) according to an instantaneous magnitude of an audio signal. For example, during a first half cycle of an audio signal, the transistor S1 is on or enabled, the transistor S2 is off or disabled, the transistor S1 can vary a magnitude of the VN voltage based on a magnitude of CS1, which can reflect/track an instantaneous magnitude of the audio signal (if operating in linear mode) during the first half cycle. Also, during a second half cycle of the audio signal, the transistor S1 is off or disabled, the transistor S2 is on or enabled, and the transistor S2 can vary a magnitude of the VN voltage based on a magnitude of CS2, which can also reflect/track an instantaneous magnitude of the audio signal during the second half cycle (if operating in linear mode). In a case where the audio signal is a sinusoidal signal, the VN voltage can be (or close to be) an amplified version of the sinusoidal signal, and the VN voltage can have a same frequency as the audio signal. On the other hand, the audio signal may also saturate the power stage PS1, in which case the VN voltage may be clipped at the PVDD voltage or at the ground voltage.

Also, the power stage PS2 comprises a third transistor S3 and a fourth transistor S4 coupled in series between a power terminal 116b (e.g., receiving a power supply PVDD) and a ground terminal. In an example, the power terminals 116a and 116b may be a same power terminal shared by both the power stages PS1 and PS2 (or the power terminals 116a and 116b may be coupled to a common power terminal), whereas in another example the power terminals 116a and 116b can be coupled to different voltage sources.

As illustrated, a first current terminal of the transistor S3 is coupled to the power terminal 116b, and a second current terminal of the transistor S3 is coupled to the output terminal 110 having a voltage of VY. A first current terminal of the transistor S4 is coupled to the output terminal 110, and a second current terminal of the transistor S4 is coupled to the ground terminal.

The transistor S3 further includes a control terminal coupled to a third power stage input that receives a control signal CS3 from a driver D3, and the transistor S4 further includes a control terminal coupled to a fourth power stage input that receives a control signal CS4 from another driver D4. The transistors S3 and S4 can set the voltage VY at output terminal 110 of the power stage PS2 responsive to control signals CS3 and CS4.

In FIG. 1B, power stage PS2 can be controlled as a switching amplifier (e.g., class D), where control signals CS3 and CS4 are pulse width modulated signals, pulse density signals, and/or any other type of modulated control signals having binary magnitudes. Depending on the magnitude of the audio signal, one of transistors S3 or S4 can be turned on to connect one of power terminal 116b or ground terminal to output terminal 110. Responsive to CS3 and CS4, power stages PS2 can also generate a modulated signal. The modulated signal provided by the power stage can have a timing property, such as duty cycle, pulse width, etc., modulated/varied to reflect an instantaneous magnitude of the audio signal. The transistors S3 and S4 can provide VY as a modulated signal at output terminal 110 responsive to CS4. The modulated signal VY at output terminal 110 can have a much higher frequency than the audio signal as well as the signal VN at output terminal 108.

In FIG. 1B, the transistors S1, S2, S3, and S4 are illustrated as n-channel metal oxide semiconductor (NMOS) field effect transistors (FETs). In other examples, the transistors S1, S2, S3, and S4 can be other types of transistors, such as p-channel MOSFET (PMOS), laterally-diffused metal-oxide semiconductor (LDMOS) FETs, Gallium Nitride (GaN) FETs, NPN or PNP bipolar junction transistor (BJT), etc.

The LC filter circuit 112 includes an inductor L1 coupled between the output terminal 110 and the speaker terminal 106, a capacitor C1 coupled between the speaker terminals 104 and 106, and another capacitor C2 coupled between the speaker terminal 104 and the ground terminal. The inductor L1 and capacitor C1 filter the modulated signal VY provided at the output terminal 110 into a sinusoidal signal VP at the speaker terminal 106 that is output to the speaker 102 to output corresponding audio. Capacitor C2 can also filter signal VN to further suppress non-linearities in the signal VN, and to provide a virtual ground with a relatively low impedance. Capacitor C2 may be relatively large (e.g., 200 nF or larger) to provide a low impedance virtual ground and reduce electromagnetic interference (EMI) and harmonic distortion in the signal VN (e.g., harmonic distortion caused by non-linear conduction angle hand-over in the power stage), as explained in related application U.S. application Ser. No. 18/385,848, entitled “METHODS AND APPARATUS TO MODULATE SIGNALS USING MULTI-CLASS MODULATION CIRCUITRY”, Attorney Docket Number T103189US01. The power stages may drive a current from few micro amps to several amps to charge up capacitor C2.

System 100 also includes a control circuit (not shown in FIG. 1B) that generates control signals that respectively drives the driver circuits D1, D2, D3, D4 based on audio signals. Example operations of system 100 are described in related U.S. application Ser. No. 17/402,264, entitled “Methods and Apparatus to Generated a Modulation Protocol to Output Audio,” filed on Aug. 13, 2021, and related U.S. application Ser. No. 17/491,133, entitled “Switching amplifier having linear transition totem pole modulation,” filed on Sep. 30, 2021, and in U.S. application Ser. No. 18/358,848, which are hereby incorporated by reference in their entireties as described above.

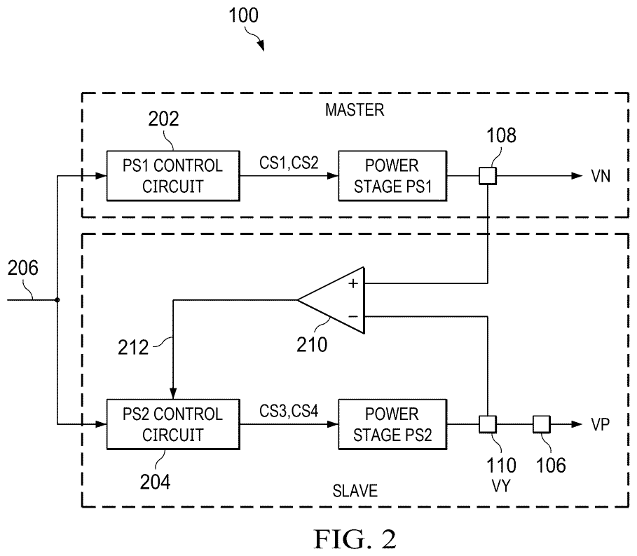

FIG. 2 illustrates examples of internal components of system 100. FIG. 2 illustrates that system 100 includes, in addition to power stages PS1 and PS2, a control circuit 202 that provides the control signals CS1 and CS2 to power stage PS1, and a control circuit 204 that provides the control signals CS3 and CS4 to power stage PS2. During startup and shutdown, both control circuits 202 and 204 may not receive an audio signal 206. During normal operation, control circuits 202 and 204 may receive audio signal 206.

In the example of FIG. 2, control circuit 202 can control power stage PS1 to operate as a non-switching amplifier (e.g., a class AB amplifier). Control circuit 202 can include a linear amplifier to generate control signals CS1 and CS2 by amplifying audio signal 206 (if present). Power stage PS1 can provide a VN voltage at first output terminal 108 having a magnitude that tracks audio signal 206. The VN voltage can also be saturated/clamped if the magnitude of audio signal 206 exceeds a certain threshold. Also, control circuit 204 can control power stage PS2 to operate as a switching amplifier (e.g., a class D amplifier). Control circuit 204 can include modulated signal generator to generate control signals CS3 and CS4 as modulated signals. In some examples, control circuit 204 can include a pulse width modulation (PWM) signal generator to generate control signals CS3 and CS4 as PWM signals, where the pulse width of CS3 and CS4 can be modulated based on an instantaneous amplitude of audio signal 206. The difference between VN and VP, after VN and VP being filtered by the LC filter circuit 112, can become an amplified audio signal.

As shown in FIG. 2, to further improve the matching between the common mode voltages between VN and VP, PS1 control circuit 202 and PS2 control circuit 204 can operate in a master-slave configuration. In the master-slave configuration, PS1 control circuit 202 and power stage PS1 is a master, and PS2 control circuit 204 and power stage PS2 is a slave. Specifically, PS1 control circuit can drive power stage PS1 based on audio signal 206 (if present), or other signals. On the other hand, PS2 control circuit 204 can include a subtraction circuit 210 (e.g., an amplifier) that receives VN and VP (or a filtered version of VY) as feedback signals and generates a difference signal 212 representing a difference between VN and VP. PS2 control circuit 204 can adjust control signals CS3 and CS4 (and VY/VP) based on difference signal 212. For example, PS2 control circuit 204 can adjust control signals CS3 and CS4 to minimize (or reduce) difference signal 212, to improve the matching between the common mode voltages of VN and VP. PS2 control circuit 204 can have a higher bandwidth than PS1 control circuit 202, which allows PS2 control circuit 204 to adjust CS3 and CS4 responsive to both audio signal 206 and difference signal 212.

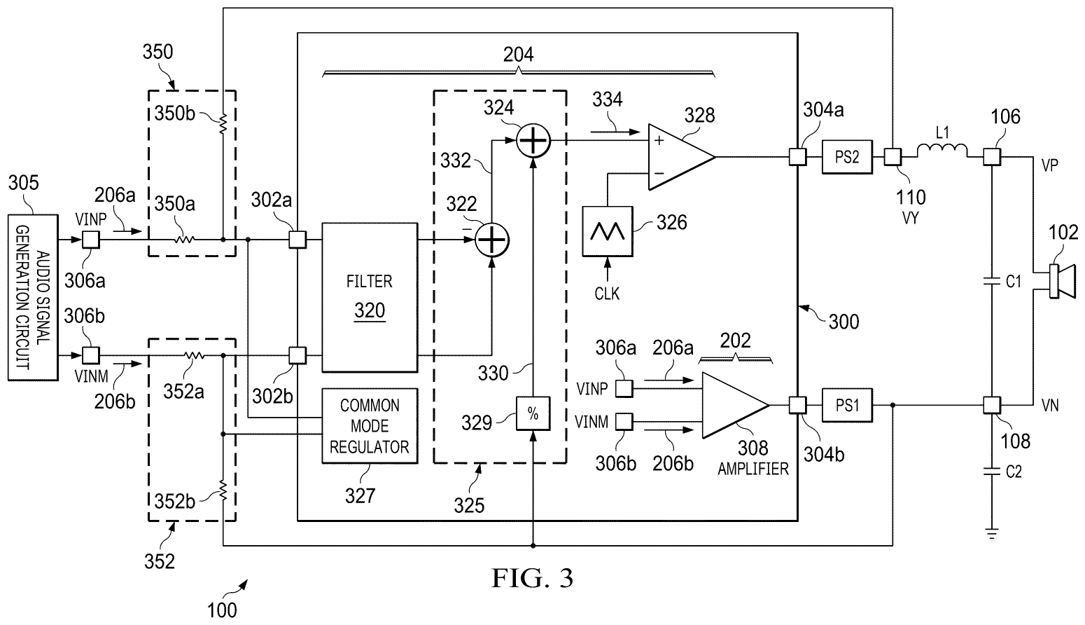

FIG. 3 illustrates examples of internal components of system 100 of FIG. 2. Referring to FIG. 3, system 100 can include an audio driver circuit 300 having driver inputs 302a, 302b, and driver outputs 304a and 304b. The driver outputs 304a and 304b are coupled to, respectively, the inputs of power stages PS1 and PS2. Audio driver circuit 300 includes PS1 control circuit 202 and PS2 control circuit 204. System 100 also includes audio inputs 306a and 306b to receive differential audio signals 206a (also labelled VINP) and 206b (also labelled VINM) of sinusoidal audio signals 206. In some examples, system 100 also includes an audio signal generation circuit 305 to provide the differential audio signals 206a/206b to audio inputs 306a and 306b. Audio signal generation circuit 306 can include a digital to analog converter (DAC) to convert a sequence of digital signals into differential audio signals 206a/206b.

PS1 control circuit 202 includes an amplifier 308 coupled to audio inputs 306a and 306b. In some examples, amplifier 308 can be a linear differential amplifier 308. Amplifier 308 can receive differential audio signals 206a and 206b, and provide control signals CS1 and CS2 by amplifying audio signals 206a and 206b to set VN voltage at first output terminal 106.

Also, PS2 control circuit 204 includes a filter 320 (e.g., a loop filter), a subtraction circuit 322, a subtraction circuit 324, a periodic ramp generator 326, a comparator 328, and a voltage scaler circuit 329. Subtraction circuit 322, subtraction circuit 324, and voltage scaler circuit 329 are collectively part of a signal combination circuit 325. In some examples, filter 320 can include a multi-stage loop filter. Voltage scaler circuit 329 provides a scaled down version of the VN voltage as a feedback signal 330. Voltage scaler circuit 329 can also remove the common mode/DC bias component of the VN voltage, and provide a scaled down version of the AC (alternating current) component of the VN voltage. Also, subtraction circuit 322 can generate a difference signal 332 representing a difference between filtered audio signals 206a and 206b and feedback signals through resistors 350b and 352b, where the difference signal 332 can have an opposite polarity from the VN voltage (and feedback signal 330). Further, subtraction circuit 324 can generate another difference signal 334 representing a difference between signals 330 and 332. Signal combination circuit 325 can represent subtraction circuit 210 of FIG. 2, and difference signal 334 can represent difference signal 212 of FIG. 2. System 100 can also include a common mode regulator 327 coupled to driver inputs 302a and 302b to define a same input common mode voltage for driver inputs 302a and 302b.

Further, comparator 328 can generate control signals CS3 and CS4 by comparing difference signal 334 with a periodic ramp signal provided by periodic ramp generator 326 and modulating the duty cycle/pulse widths of CS3 and CS4 based on the difference. Periodic ramp generator 326 can receive a clock signal (labelled CLK) and generate the periodic ramp signal synchronized to the clock signal and having a cycle period defined based on the clock signal. Difference signal 334 can have a component representing the audio signals 206 and a corrective component representing the difference between VP and VN caused by, for example, the aforementioned asymmetry and non-linear effects. Accordingly, the duty cycle/pulse widths of CS3 and CS4 can reflect the instantaneous magnitudes of audio signals 206a and 206b (represented by difference signal 332) and a difference between VP and VN (as part of the master-slave configuration), and control circuit 204 can adjust CS3 and CS4 to reduce/minimize the aforementioned difference between VP and VN caused by asymmetry and non-linear effects.

Also, system 100 can also include a pair of resistor networks 350 and 352 to set an overall amplification gain of the system. The overall amplification gain can be between the differential output voltage VP-VN (or VY-VN) and the differential input voltage VINP-VINM. System 100 can include resistor network 350 for the signal path from VINP to VY, and resistor network 352 for the signal path from VINM to VN. Resistor network 350 can include an input resistor 350a coupled between audio input 306a and driver input 302a, and a feedback resistor 350b coupled between driver input 302a and output terminal 110. Also, resistor network 352 can include an input resistor 352a coupled between audio input 306b and driver input 302b, and a feedback resistor 352b coupled between driver input 302b and output terminal 108. Resistor networks 350 and 352 are to be matched, where input resistors 350a and 352a have a same resistance (e.g., RIN) and feedback resistors 350b and 352b have a same resistance (e.g., RFB), to remove a component of differential output voltage VP-VN (or VY-VN) caused by the output common mode voltage VCM, and to provide an amplification gain for the differential input voltage VINP-VINM.

In audio system 100, the output of the power stage PS2 is coupled to inductor L1, which can discharge to provide a current to speaker 102 via terminal 106, thereby driving terminal 106 at voltage VP. Accordingly, power stage PS2 may provide a current to charge inductor L1, which can also improve the power efficiency of power stage PS2. In contrast, the output of power stage PS1 is coupled to capacitor C2 and output terminal 108, which is coupled to terminal 104 of speaker 102. Power stage PS1 may provide a current to charge/discharge capacitor C2, and to provide a current to speaker 102 via terminals 104/108, thereby driving terminals 104/108 at the VN voltage.

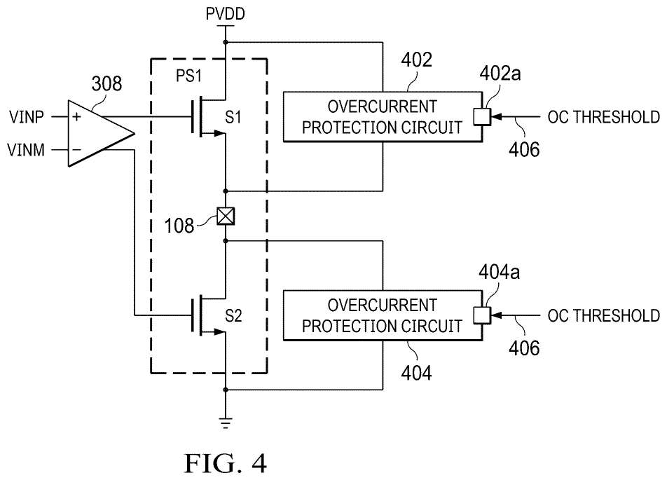

In some examples, to improve safety and reliability, audio system 100 may include an overcurrent protection circuit coupled to the power stage PS1. Audio system 100 may also include an overcurrent protection circuit coupled to the power stage PS2. FIG. 4 illustrates an example of overcurrent protection circuits 402 and 404. Referring to FIG. 4, audio system 100 may include an overcurrent protection circuit 402 coupled to transistor S1 of power stage PS1, and an overcurrent protection circuit 404 coupled to transistor S2 of power stage PS1. Each of overcurrent protection circuits 402 and 404 has a respective overcurrent threshold control inputs (402a and 404a) to receive an overcurrent threshold signal 406. In some examples, the overcurrent threshold represented by overcurrent signal 406 can be pre-determined and can remain static during the operation of audio system 100.

Overcurrent protection circuit 402 can include a current sensor (e.g., a resistor, a transistor, etc.) to sense a current conducted between current terminals (e.g., drain and source terminals) of transistor S1, and compare the current against an overcurrent threshold represented by signal 406. If the current exceeds the overcurrent threshold, overcurrent protection circuit 402 may perform one or more actions, such as disabling transistor S1 (e.g., disconnecting the control terminal of transistor S1 from amplifier 308, or causing amplifier 308 to disable transistor S1), disconnecting transistor S1 from the power supply PVDD, etc., to prevent the excessive current from damaging transistor S1 or creating overheating.

Also, overcurrent protection circuit 404 can sense a current conducted between current terminals (e.g., drain and source terminals) of transistor S2, and compare the current against an overcurrent threshold represented by signal 406. If the current exceeds the overcurrent threshold, overcurrent protection circuit 402 may perform one or more actions, such as disabling transistor S2 (e.g., disconnecting the control terminal of transistor S2 from amplifier 308, or causing amplifier 308 to disable transistor S2), disconnecting transistor S2 from the ground terminal, etc., to prevent the excessive current from damaging transistor S2 or creating overheating.

Although overcurrent protection circuits 402 and 404 can enhance the reliability and safety of operation of power stage PS1, they can be falsely triggered by transient events and disable power stage PS1, which disrupts the operation of audio system 100. Such disruption is especially undesirable if it occurs when audio system 100 is outputting sound via speaker 102.

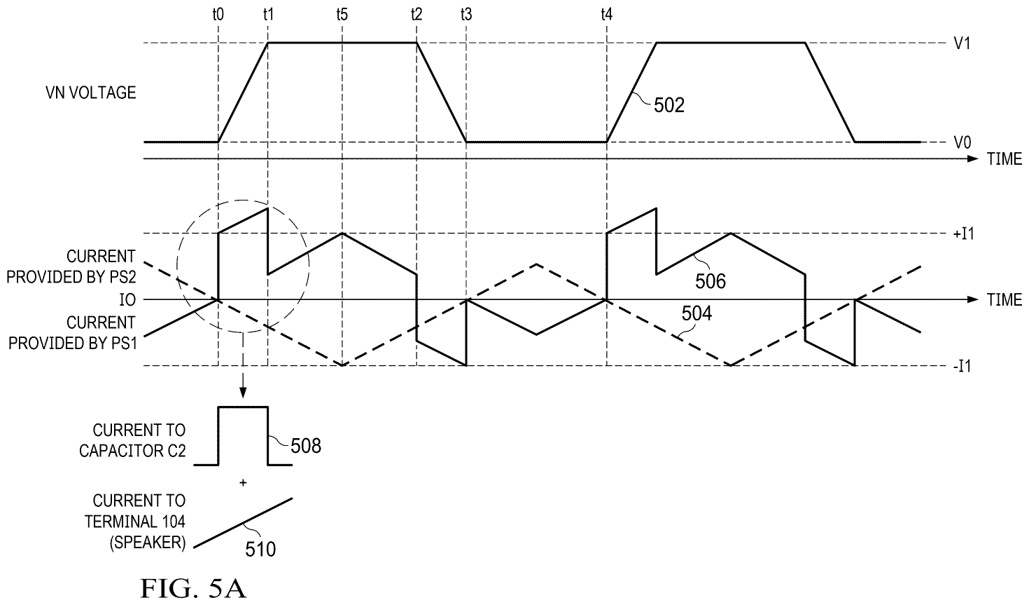

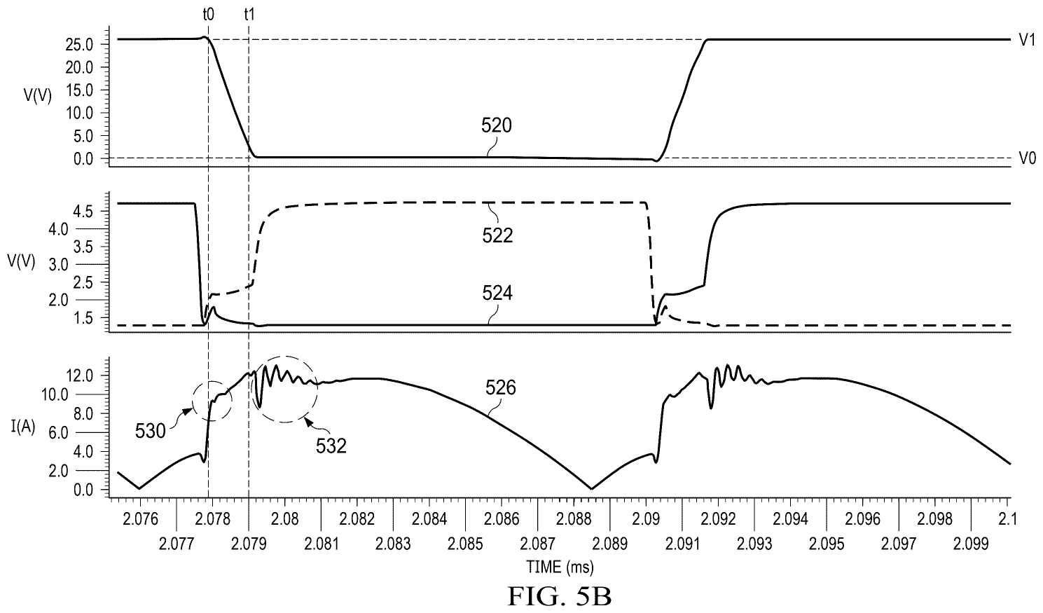

FIG. 5A include graphs illustrating example operations of audio system 100 that can cause false trigger to overcurrent protection circuits 402 and 404. FIG. 5A includes graphs 502, 504, 506, 508, and 510. Graph 502 illustrates an example variation of the VN voltage at the output of the power stage PS1 with time, including linear region(s) where the VN voltage is a linear amplified version of the audio signal, and saturation region(s) where the VN voltage is clipped. Graph 504 illustrates an example variation of the current provided by the power stage PS2 with time. Graph 506 illustrates an example variation of the current provided by the power stage PS1 with time. Graphs 508 and 510 illustrate components of the current provided by the power stage PS1 within an interval between times t0 and t1.

Referring to graph 502, the VN voltage at the output of the power stage PS1 rises from voltage V0 to voltage V1 between times t0 and t1, and is clamped at voltage V1. Voltage V1 can be equal to the supply voltage PVDD. The VN voltage drops from voltage V1 back to V1 between times t2 and t3, and the pattern repeats at time t4. Audio system 100 can operate in the linear region with a high slew rate between t0 and t1 and between t2 and t3, and operate in the saturation region between t1 and t2.

Also, referring to graph 504, the current provided by the power stage PS2 follow a triangular pattern. For example, the current provided by the power stage PS2 can be at 0 at time t0 and decrease linearly to −I1 at time t5 between t1 and t2, and increase linearly back to I0 at time t3. The current provided by the power stage PS2 can drive speaker 102.

Further, referring to graph 506, the current provided by the power stage PS1 can be a sum of the current provided to charge/discharge capacitor C2 and the current provided to speaker 102 via terminal 104. The current provided to speaker 102 via terminal 104 can follow the same triangular pattern as the current provided by the power stage PS2 (represented by graph 504) but with opposite polarity. For example, while the current provided by the power stage PS2 decreases linearly from 0 to −I1 between times t0 and t5, the current provided by the power stage PS1 increases linearly from 0 to +I1 between times t0 and t5, as shown in graph 510.

In addition to providing a current to speaker 102, the power stage PS1 also provides a current to charge/discharge capacitor C2. The charging/discharging of capacitor C2 occurs during the transition of the VN voltage between V0 and V1. For example, between times t0 and t1 when the VN voltage increases from V0 to V1, the power stage PS1 provide a current to charge capacitor C2, as shown in graph 508. The amount of current provided by the power stage PS1 can be based on a target slew rate of the VN voltage, which can depend on the input voltage slew rate and/or the input voltage amplitude at amplifier 308. For example, if the input voltage slew rate/amplitude is high, the VN voltage, which tracks the input voltage, can also have a high target slew rate. To reach the high target slew rate for the VN voltage, the power stage PS1 can provide a higher current to speed up the charging of the capacitor C2. But the additional current provided by the power stage PS1 during the transition times of the VN voltage can lead to current spikes. In some examples, the current spike can exceed 12 amperes (A). If the input voltage slew rate/amplitude is high, such current spikes can be high enough to falsely trigger the overcurrent protection circuit to disable the flow of current in the power stage PS1 and disrupts the operation of audio system 100. Such disruption is especially undesirable if it occurs when audio system 100 is outputting sound via speaker 102.

In addition to charging/discharging of capacitor C2, current spikes may also occur due to stability ringing introduced by amplifier 308 and parasitic ringing. FIG. 5B includes graphs that illustrate examples of current spikes caused by parasitic ringing. FIG. 5B includes graphs 520, 522, 524, and 526. Graph 520 illustrates an example variation of the VN voltage at the output of the power stage PS1 with time. Graph 522 illustrates an example variation of the gate/control terminal voltage of transistor S1 with time. Graph 524 illustrates an example variation of the gate/control terminal voltage of transistor S2 with time. Graph 526 illustrates an example variation of the current provided by the power stage PS1 with time. The operation conditions depicted in graphs 520, 522, 524, and 526 of FIG. 5B can similar to the graphs 502-510 of FIG. 5A.

Referring to graphs 522-524 of FIG. 5B, between times t0 and t1, the gate voltage of transistor S1 falls to close to zero, and transistor S1 is disabled. Also, the gate voltage of transistor S2 starts increasing to turn on transistor S2. The VN voltage transitions from V1 (25V in FIG. 5B) to V0 (0V in FIG. 5B). Referring to graph 526, a current spike results from the charging of capacitor C2 between t0 and t1, similar to the current spike shown in graph 506 of FIG. 5A. On top of the current spike results from the charging of capacitor C2, there is also ringing 530 caused by the sudden change in the charging current of the C2 capacitor.

The current spike can further increase if the load has a high inductance (e.g., a heavily inductive speaker, such as a piezoelectric speaker), where the load current can be 90 degrees out of phase with the voltage across the load, thus a peak in the load current can occur during the high slew-rate transition of the load voltage (e.g., VN voltage). The load current for driving a high inductive load can be much larger than a load current for driving a resistive load, where the current is proportional to the load voltage. Accordingly, with a large load current to begin with, even without the current spike from the charging of the C2 capacitor, the overcurrent protection circuit can be falsely triggered. With the current spike from the charging of the C2 capacitor coinciding with the peak load current due to the load current being 90 degree out of phase with the load voltage, the overall current spike can be further increased, which can lead to more false triggering of the overcurrent protection circuit.

Also, ringing can introduce additional spikes. For example, ringing 530 can introduce additional spikes to the current provided by the power stage PS1 between t0 and t1. Also, after t1, capacitor C2 is fully charged, but the current provided by the power stage PS1 can exhibit additional ringing. The ringing can be caused by parasitic inductance at the output of the power stage PS1. The parasitic ringing can further increase the amplitude of the current spike. In the example shown in FIG. 5B, the parasitic ringing can further increase the amplitude of the current spike to above 12A. Because of the all these current spikes, the overcurrent protection circuit can be falsely triggered to disable the power stage PS1. The excessive current spikes can occur in an audio system 100, or any system can use a non-switching amplifier to drive a large capacitive load in addition to an actual load.

One possible way of avoiding the false triggering is by blanking/disabling the overcurrent protection circuit during the transition period of the VN voltage. For example, referring to FIG. 5, overcurrent protection circuits 402 and 404 can be blanked/disabled within intervals between t0 and t1, t2 and t3, etc., and overcurrent protection circuits 402 and 404 do not sense the current through transistors S1 and S2, or otherwise do not provide an overcurrent detection output, during those intervals. While such arrangements can avoid the false triggering, blanking/disabling overcurrent protection circuits 402 and 404 during the transition period of the VN voltage may introduce safety/reliability hazard. Specifically, if an electrical short is created by transistors S1 and S2 between the power supply PVDD and the ground terminal during the transition period of the VN voltage, the current conducted by transistors S1 and S2 can be far higher (e.g., 50A) than the current spikes caused by charging/discharging of capacitor C2. The transition period is also relatively long. If such electrical short occurs within the transition period, and the overcurrent protection circuits 402 and 404 are disabled/blanked and hence transistors S1 and S2 cannot be disabled to stop the flow of a large current, transistors S1 and S2 can be damaged, and overheating of audio system 100 may also occur.

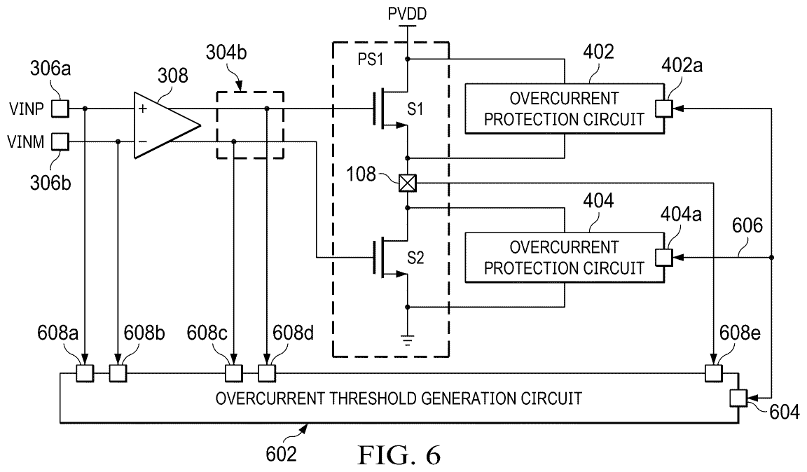

FIG. 6 illustrates an example of a circuit that can address at least some of issues described above. Referring to FIG. 6, audio system 100 can include, in addition to overcurrent protection circuits 402 and 404, an overcurrent threshold generation circuit 602. Overcurrent threshold generation circuit 602 has a threshold output 604 coupled to overcurrent threshold control inputs 402a (of overcurrent protection circuit 402) and 404a (of overcurrent protection circuit 404). Overcurrent threshold generation circuit 602 also has one or more control inputs 608 coupled to amplifier 308 and/or power stage PS1. In some examples, overcurrent threshold generation circuit 602 may have control inputs 608a and 608b coupled to audio inputs 306a and 306b of audio system 100 which are coupled to the inputs of amplifier 308. In some examples, overcurrent threshold generation circuit 602 may have control inputs 608c and 608d coupled to driver output(s) 304b, which are coupled to the outputs of amplifier 308 and inputs of the power stage PS1. In some examples, overcurrent threshold generation circuit 602 may have a control inputs 608e coupled to output terminal 108 of the power stage PS1.

From one or more of control inputs 608a-e, overcurrent threshold generation circuit 602 can receive a signal indicative of a slew rate of the VN voltage at output terminal 108 of the power stage PS1, and provide an overcurrent threshold signal 606 at threshold output 604 based on the slew rate and whether or not the power stage PS1 operates in the linear region. Specifically, as to be described in details below, in some examples, overcurrent threshold generation circuit 602 can provide a default overcurrent threshold outside the transition intervals (e.g., the intervals between t0 and t1 and between t2 and t3 in FIG. 5) of the VN voltage. During the transition intervals where the VN voltage transitions between a first voltage (e.g., V0) and a second voltage (e.g., V1) and where the power stage PS1 operates in the linear region, and overcurrent threshold generation circuit 602 can measure the slew rate of the VN voltage, and increase the default overcurrent threshold based on the slew rate. In some examples, overcurrent threshold generation circuit 602 can compare the slew rate against a slew rate threshold, and increase the default overcurrent threshold by a certain amount if the slew rate exceeds the slew rate threshold. In some examples, overcurrent threshold generation circuit 602 can also compare the slew rate against multiple slew rate thresholds representing different slew rate ranges, and increase the default overcurrent threshold by an amount based on which range the slew rate is in. In some examples, overcurrent threshold generation circuit 602 can also determine the value of the slew rate, and adjust the overcurrent threshold so that the threshold is proportional to the slew rate value. All these allow the overcurrent threshold to be adjusted in finer granularity, and the overcurrent threshold can more precisely represent the amplitude of the current spike.

With such arrangements, audio system 100 can dynamically increase the overcurrent threshold based on the slew rate of the VN voltage at the output of the power stage PS1. The overcurrent threshold can be increased to reflect the temporary current spike caused by the charging/discharging of capacitor C2, which can avoid the current spike falsely triggering the overcurrent protection circuit to disable the power stage PS1 while allowing the overcurrent protection circuit to detect and respond to other high current events, such as excessive current caused by electrical shorts in the power stage PS1. Accordingly, disruption to the operation of audio system 100 due to false triggering of overcurrent protection circuits can be reduced, while the reliability and safety of audio system 100 can still be maintained as the overcurrent protection circuits can still detect and respond to high current events, especially during the transition intervals of the VN voltage.

In some examples, as to be described in details below, after increasing the overcurrent threshold from a default value, overcurrent threshold generation circuit 602 can wait for a certain interval before adjusting the overcurrent threshold back to the default value. Such arrangements allow overcurrent threshold to be increased not just to account for the current spikes during the transition interval of the VN voltage but also to account for the parasitic ringing after the transition interval ends, as shown in FIG. 5B. Also, during the intervals when the VN voltage is clamped (e.g., between times t1 and t2 of FIG. 5A), there may be no current spike during the normal operation of the power stage PS1. Accordingly, during the intervals when the VN voltage is clamped, overcurrent threshold generation circuit 602 can maintain the overcurrent threshold at the default value and does not adjust the overcurrent threshold based on the slew rate at the output of the power stage PS1. All these can improve the overall robustness of overcurrent protection.

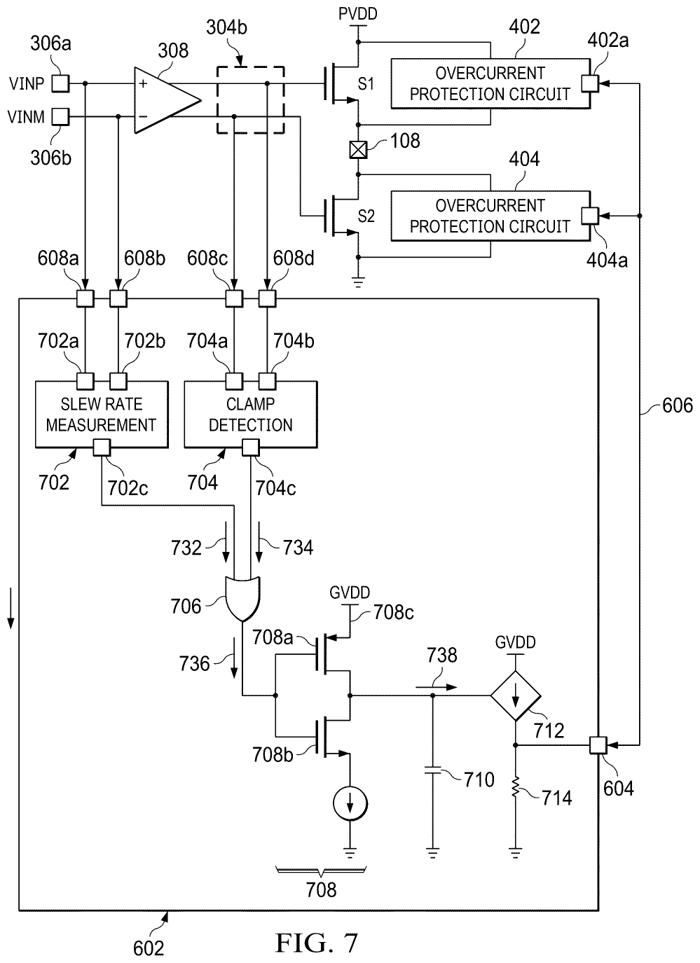

FIG. 7 illustrates examples of internal components of overcurrent threshold generation circuit 602. Referring to FIG. 7, in some examples, overcurrent threshold generation circuit 602 includes a slew rate measurement circuit 702, a clamp detection circuit 704, a logic gate 706, an inverter circuit 708, a capacitor 710, a controllable current source 712, and a resistor 714. Slew rate measurement circuit 702 has inputs 702a and 702b coupled to control inputs 608a and 608b of overcurrent threshold generation circuit 602 and to audio inputs 306a and 306b, and an output 702c. Clamp detection circuit 704 has inputs 704a and 704b coupled to control inputs 608c and 608d of overcurrent threshold generation circuit 602 and to driver output 304b, and an output 704c. The output 702c of slew rate measurement circuit 702 and the output 704c of clamp detection circuit 704 are coupled to the inputs of logic circuit 706. The output of logic circuit 706 is coupled to the input of inverter circuit 708, which includes a pull-up transistor 708a, a pull-down transistor 708b, and a current source 708c coupled between pull-down transistor 708b and the ground. The output of inverter circuit 708 is coupled to a control input of controllable current source 712. Controllable current source 712 is coupled between a power supply (e.g., GVDD) and threshold output 604, and resistor 714 is coupled between threshold output 604 and the ground terminal.

In some examples, slew rate measurement circuit 702 can measure a slew rate of the input voltage VINP at audio input 308a and/or the input voltage VINM at 308b, and provide a slew rate signal 732 indicative of a slew rate of the VN voltage at the power stage PS1 at output 702c. As described above, because amplifier 308 drives the power stage PS1 as a non-switching amplifier (e.g., a class A amplifier, a class AB amplifier, etc.), the VN voltage provided by the power stage PS1 can track the input voltages VINP/VINM at least until the VN voltage saturates. Accordingly, by measuring the slew rate of the input voltage VINP/VINM, slew rate measurement circuit 702 can provide slew rate signal 732 indicative of a slew rate of the VN voltage at the power stage PS1. In other examples, inputs 702a/b of slew rate measurement circuit 702 are coupled to driver output 304b or output terminal 108 of the power stage PS1 (e.g., via control input 608e) to measure the slew rate of the VN voltage.

Moreover, measuring the slew rate of the input voltage VINP/VINM can provide a feedforward signal indicative of (or predictive of) a slew rate of the VN voltage at the power stage PS1. Because it takes time for amplifier 308 and the power stage PS1 to adjust the VN voltage responsive to the input voltage VINP/VINM, such a feedforward mechanism allows overcurrent threshold generation circuit 602 to respond to the (predicted) slew rate of the VN voltage and adjust overcurrent threshold signal 606 in parallel to amplifier 308 and the power stage PS1 to generating the VN voltage responsive to the input voltage VINP/VINM. Such arrangements provides additional time for overcurrent threshold generation circuit 602 to adjust overcurrent threshold signal 606 based on the slew rate of the VN voltage, which in turn can relax the bandwidth/speed requirement of slew rate measurement circuit 702 and the overall bandwidth/speed requirement of overcurrent threshold generation circuit 602. In a case where a slow circuit is used to measure the slew rate of the VN voltage directly, the slow circuit may be unable to detect the high slew rate due to its limited bandwidth and adjust the threshold accordingly, which can lead to false triggering of the overcurrent protection circuit. The relaxation of the overall bandwidth/speed requirement of overcurrent threshold generation circuit 602 can prevent or reduce the likelihood of false triggering of the overcurrent protection circuit caused by the limited bandwidth/speed of overcurrent threshold generation circuit 602. Further, the input voltage VINP/VINM can be in a lower voltage domain than the VN voltage, which allows slew rate measurement circuit 702 to be implemented using low voltage transistor devices that can provide higher bandwidth.

In some examples, clamp detection circuit 704 can detect whether the VN voltage is clamped/saturated. As described above, during the intervals when the VN voltage is clamped (e.g., between times t1 and t2 of FIG. 5A), there may be no current spike during the normal operation of the power stage PS1. Accordingly, during the intervals when the VN voltage is clamped, overcurrent threshold generation circuit 602 can maintain the overcurrent threshold at the default value and does not adjust the overcurrent threshold based on the slew rate at the output of the power stage PS1. Clamp detection circuit 702 can detect whether the VN voltage is clamped, and upon detecting the VN voltage is clamped, provide a clamp detection signal 734 that allows logic gate 706 to mask slew rate signal 732, or otherwise prevent overcurrent threshold generation circuit 602 from increasing the overcurrent threshold. As to described below, clamp detection circuit 702 can receive control signals CS1/CS2 at driver output 304b (via control inputs 608c/608d of overcurrent threshold generation circuit 602), or voltage VN at output terminal 108 of the power stage PS1 (via control input 608e), and provide clamp detection signal 734 indicative of (or predictive of) whether the voltage VN is clamped/saturated. Measuring the control signals CS1/CS2 allows clamp detection circuit 702 to generate clamp detection signal 734 as a feedforward signal and relax the bandwidth/speed requirement of clamp detection circuit 702, which provides similar benefits as slew rate measurement circuit 702 generating slew rate signal 732 as a feedforward signal. Also, the control signals CS1/CS2 can be in a lower voltage domain than the VN voltage, which also allows clamp detection circuit 704 to be implemented using low voltage transistor devices that can provide higher bandwidth.

Logic gate 706 can provide a control signal 736 based on slew rate signal 732 and clamp detection signal 734. As described above, logic gate 706 can mask slew rate signal 732 based on a state of clamp detection signal 734. If clamp detection signal 734 indicates that the voltage VN is (or will be) clamped/saturated, logic gate 706 can provide control signal 736 by masking/ignoring slew rate signal 732 to maintain the overcurrent threshold at a default value. If clamp detection signal 734 indicates that the voltage VN is not (or will not be) clamped/saturated, logic gate 706 can provide control signal 736 by forwarding slew rate signal 732.

In the example of FIG. 7, slew rate signal 732 can be active low, where if the slew rate exceeds a threshold, slew rate signal 732 can be in a low logic state. Also, clamp detection signal 734 can be active low, where if the VN voltage is clamped, clamp detection signal 734 can have a high logic state, and if the VN voltage is not clamped, clamp detection signal 734 can have a low logic state. Accordingly, control signal 738 can be in a low logic state (and control signal 736 is a high logic state) if clamp detection signal 736 is in the high logic state regardless of the state of slew rate signal 732. If clamp detection signal 734 is in the low logic state, the logic state of control signal 736 can track the logic state of slew rate signal 732. If slew rate signal 732 also has a low logic state (indicating that the slew rate exceeds a threshold), control signal 736 can have a low logic state, and control signal 738 can have a high logic state. But if slew rate signal 732 has a high logic state (indicating that the slew rate is below the threshold), control signal 736 can have a high logic state, and control signal 738 can have a low logic state.

Inverter circuit 708 can generate control signal 738 for the controllable current source 712 responsive to the state of control signal 736. If control signal 736 is in the low logic state, which indicates that the slew rate exceeds the threshold, inverter circuit 708 can pull control signal 738 up to a high logic state by charging capacitor 710 via transistor 708a. Also, if control signal 736 is in the high logic state, which indicates that the slew rate is below the threshold and/or the VN voltage is clamped, inverter circuit 708 can pull down control signal 738 to a low logic state by discharging capacitor 710 via transistor 708b and current source 708c.

Also, controllable current source 712 can provide a current, based on the state of control signal 738, to generate a voltage across resistor 714, and the voltage sets the overcurrent threshold. If control signal 738 is in the low logic state (indicating the slew rate exceeds the threshold), controllable current source 712 can increase the current through resistor 714, which increases the voltage of the overcurrent threshold signal 606 and represents an elevated overcurrent threshold. Also, if control signal 738 is in the high logic state (indicating that the overcurrent threshold is not to be adjusted upwards), controllable current source 712 can provide a default current through resistor 714, which reduces the voltage of the overcurrent threshold signal 606 back to a default value and represents the default overcurrent threshold.

In some examples, as shown in FIG. 7, inverter circuit 708 can have a slow pull-down and a fast pull-up configuration, where the pull-down speed is limited by current source 708c. Such an arrangement can introduce a delay in reducing the overcurrent threshold back to the default value. As described above with respect to FIG. 5B, after charging of capacitor C2 completes, the current provided by the power stage PS1 can experience parasitic ringing, which can introduce additional current spikes. To prevent those current spikes from falsely triggering the overcurrent protection circuits, overcurrent threshold generation circuit 602 can maintain the overcurrent threshold at an elevated level for an extended amount of time after increasing the overcurrent threshold. The slow pull-down configuration of inverter circuit 708 can provide the extended time for maintain the overcurrent threshold at the elevated level before reducing it back to the default level.

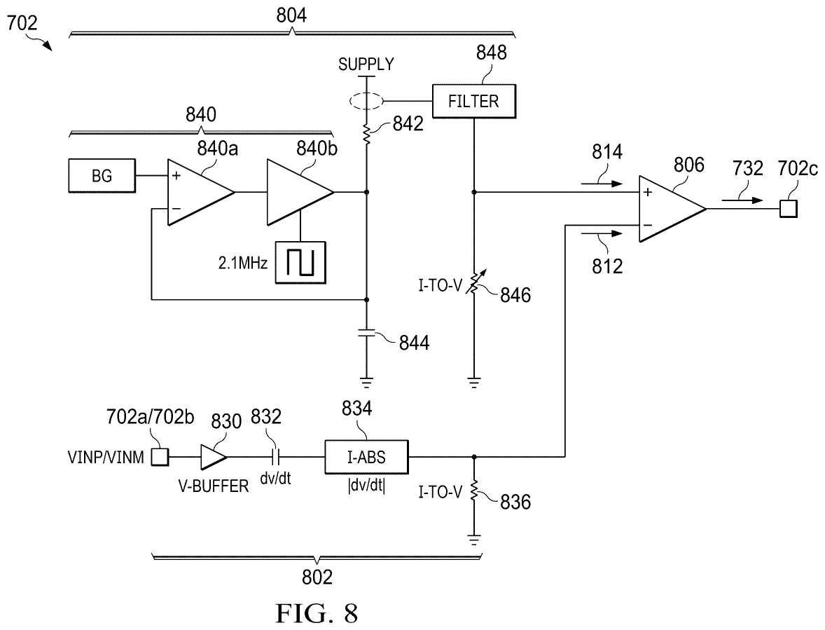

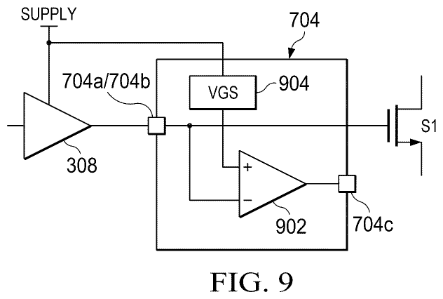

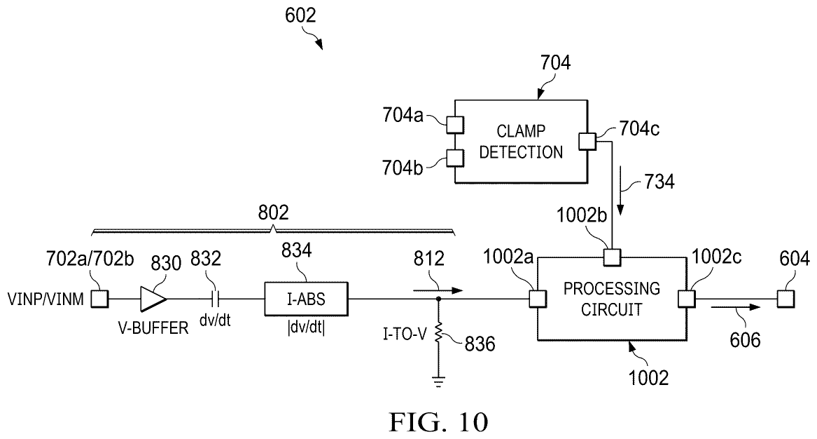

FIG. 8 illustrates examples of internal components of slew rate measurement circuit 702. Referring to FIG. 8, components of slew rate measurement circuit 702 has a measurement path 802, a reference path 804, and a comparator 806. Measurement path 802 are coupled to inputs 702a and 702b. Measurement path 802 can receive an input voltage (e.g., one of audio signals VINP/VINM as shown in FIG. 8, or a voltage at driver output 304b, a voltage at output terminal 108), and generate a signal 812 representing a slew rate of the input voltage. Reference path 804 can generate a signal 814 representing a slew rate reference. Comparator 806 has an output coupled to output 702c. Comparator 806 can compare signal 812 against signal 814. If the slew rate of the input voltage exceeds the slew rate reference, comparator output 806 can provide control signal 732 having a low logical state. If the slew rate of the input voltage is below the slew rate reference, comparator output 806 can provide control signal 732 having a high logical state.

In some examples, measurement path 802 includes a voltage buffer 830, a capacitor 832, an absolute value circuit 834, and a resistor 836. Voltage buffer 830 has an input coupled to inputs 720a orb to receive the input voltage (VINP or VINM), and provide a buffered version of the voltage. Capacitor 832 is coupled between the output of voltage buffer 830 and the input of absolute value circuit 834 and is configured as an alternating current (AC) capacitor or a high pass filter, where capacitor 832 can provide a current representing the edge rate of a transition edge (e.g., a rising edge between t0 and t1 in FIG. 5A, a falling edge between t2 and t3 in FIG. 5A, etc.) to absolute value circuit 834 while blocking low frequency content. The flow direction of the current provided by capacitor 832 depends on whether capacitor 832 receives a rising edge or a falling edge. Absolute value circuit 834, which can include a rectifier, can generate a current signal representing the magnitude of the current provided by capacitor 832, and provide the current signal to resistor 836, which converts the current signal to a voltage signal 812 representing the slew rate. Accordingly, absolute value circuit 834 can provide a current signal representing the slew rate of the input voltage irrespective of whether the input voltage increases or decreases. This also allows measurement path 802 to receive one of VINP or VINM which are differential signals having the same magnitude but opposite polarities.

Also, reference path 804 includes a pulse generator 840, a resistor 842, a capacitor 844, a current sensor and filter 848, and a resistor 846. Pulse generator 840 has an output coupled to capacitor 844 and can apply voltage pulses to capacitor 844. Pulse generator 840 can include a voltage regulator circuit 840a to set an amplitude of the voltage pulse based on a bandgap reference voltage, and a switch circuit 840b to toggle the state of the voltage pulse. The rising and falling edges of capacitor 844 can cause a current to flow through resistor 842. Current sensor and filter 848 can sense the current and provide an average of the current through resistor 846 to generate a voltage signal 814 representing the slew rate reference.

In some examples, to reduce the variation of the slew rate reference provided by reference path 214 with respect to the actual slew rate measured by measurement path 804 caused by process, voltage, and temperature (PVT), capacitors 832 (that generates voltage signal 812) and 844 (that generates voltage signal 814) can be matched, and resistors 836 and 846 can be matched. The matching can be based on, for example, using same materials of fabrication, being in close proximity in the chip, and/or various layout techniques such as interdigitation. This allows voltage signal 812 (from measurement path 804) and reference signal 814 (from reference path 802) to track the same PVT variations.

FIG. 9 illustrates examples of internal components of clamp detection circuit 704. Referring to FIG. 9, in some examples, clamp detection circuit 704 includes a comparator 902 having a negative input coupled to driver output 304b via inputs 704a/b. The positive input of comparator 902 receives a reference voltage representing a clamping condition. In some examples, as shown in FIG. 9, clamp detection circuit 704 can include a voltage drop circuit 904 to generate the reference voltage. —The reference voltage can be with respect to the S1 source to track the threshold voltage variation of the transistor S1 (e.g., due to PVT variations). Voltage drop circuit 904 can be coupled between a supply voltage of amplifier 308 and the positive input of comparator 902. The reference voltage generated by voltage drop circuit 904 can represent the gate voltage of transistor S1 when transistor S1 is fully turned on, and output terminal 108 is clamped/saturated at the PVDD supply voltage of the power stage PS1.

FIG. 10 illustrates another example of overcurrent threshold generation circuit 602. Referring to FIG. 10, overcurrent threshold generation circuit 602 includes the measurement path 802 of FIG. 8 and a processing circuit 1002. Processing circuit 1002 has an input 1002a, an input 1002b, and an output 1002c. Input 1002a is coupled to measurement path 802 to receive voltage signal 812. Input 1002b is coupled to output 704c of clamp detection circuit 704 to receive clamp detection signal 734. Output 1002c is coupled to threshold output 604 to provide overcurrent threshold signal 606. Processing circuit 1002 can include digital circuits (e.g., look up table (LUT), analog circuits (e.g., amplifiers, analog to digital converter (ADC), digital to analog converter (DAC), etc.), or a mixture of both, to generate overcurrent threshold signal 606 based on voltage signal 812 and clamp detection signal 734. For example, if clamp detection signal 734 indicates that the power stage is operating in the linear region, processing circuit 1002 can generate an overcurrent threshold signal 606 by adding an offset to a default overcurrent threshold, where the offset is proportional to the slew rate value. In a case where processing circuit 1002 includes LUT, the LUT can map multiple ranges of input digital values to different overcurrent threshold values, and selectively output one of the different overcurrent threshold values based on which range the input digital value maps to, if clamp detection signal 734 indicates that the power stage is operating in the linear region. On the other hand, if clamp detection signal 734 indicates that the power stage is operating in the saturation region, processing circuit 1002 can provide overcurrent threshold signal 606 representing the default overcurrent threshold.

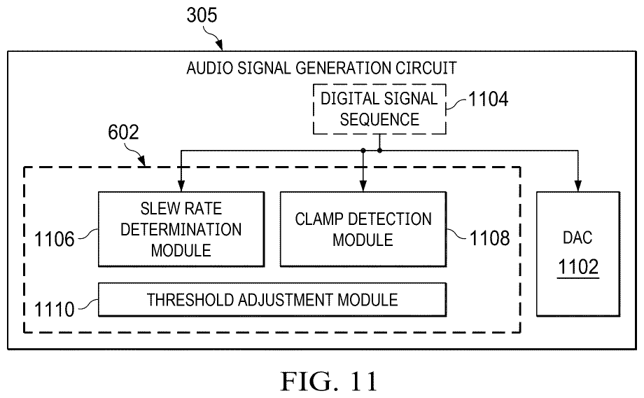

In some examples, overcurrent threshold generation circuit 602 can be part of audio signal generation circuit 305 of FIG. 3. FIG. 11 illustrates examples of internal components of audio signal generation circuit 305 including overcurrent threshold generation circuit 602. As described above, in some examples, audio signal generation circuit 305 can include a digital to analog converter (DAC) 1102 to convert a sequence of digital signals 1104 into differential audio signals 206a/206b. Overcurrent threshold generation circuit 602 as part of audio signal generation circuit 305 can include a slew rate determination module 1106, a clamp detection module 1108, and a threshold adjustment module 1110. Both slew rate determination module 1106 and clamp detection module 1108 can access the sequence of digital signals 1104 and determine first intervals where the output of power stage PS1 have high slew rates based, for example, determining derivatives of the digital signals with respect time, similar to as shown in FIG. 8 and FIG. 9, and based on the delay between when DAC 1102 sends out audio signals 206a/206b and the time when the power stage PS1 generates the VN voltage. Clamp detection module 1108 can determine, based on comparing the digital signals with one or more amplitude thresholds, and also based on the information about the voltage supply of the power stage PS1 (PVDD) and the overall gain of amplifier 308 and the power stage PS1, second intervals where the output of power stage PS1 are clamped/saturated. Threshold adjustment module 1110 can then adjust the overcurrent threshold at subsets of first intervals that do not overlap with the second intervals. Slew rate determination module 1106, clamp detection module 1108, and threshold adjustment module 1110 can be part of an application specific integrated circuit (ASIC) including both analog and digital circuits, digital logic circuits, or software modules implemented on a processor (e.g., digital signal processor) and/or on a programmable logic circuit such as a field programmable gate array (FPGA) circuit, etc.

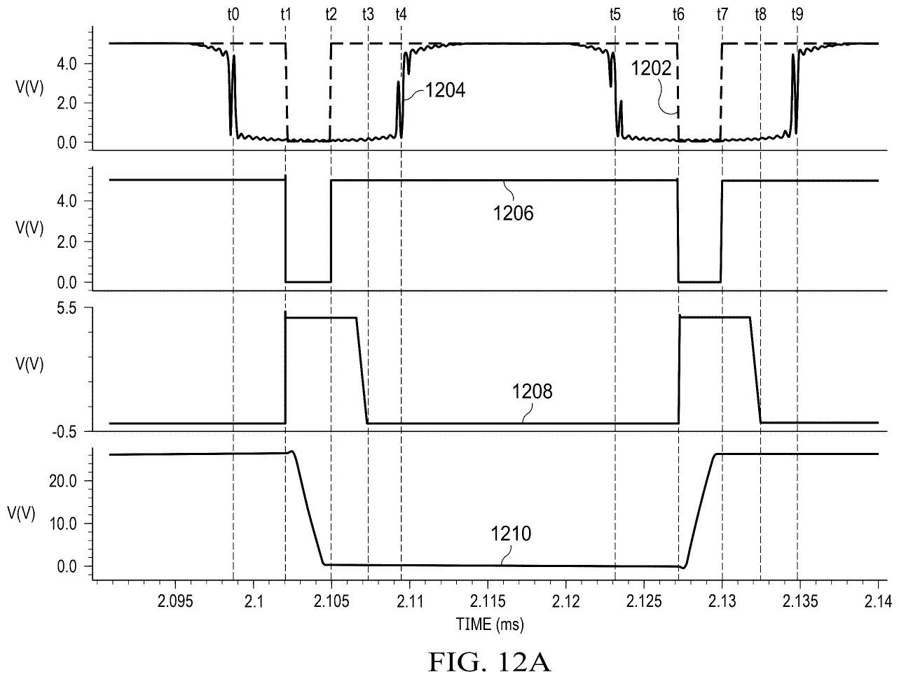

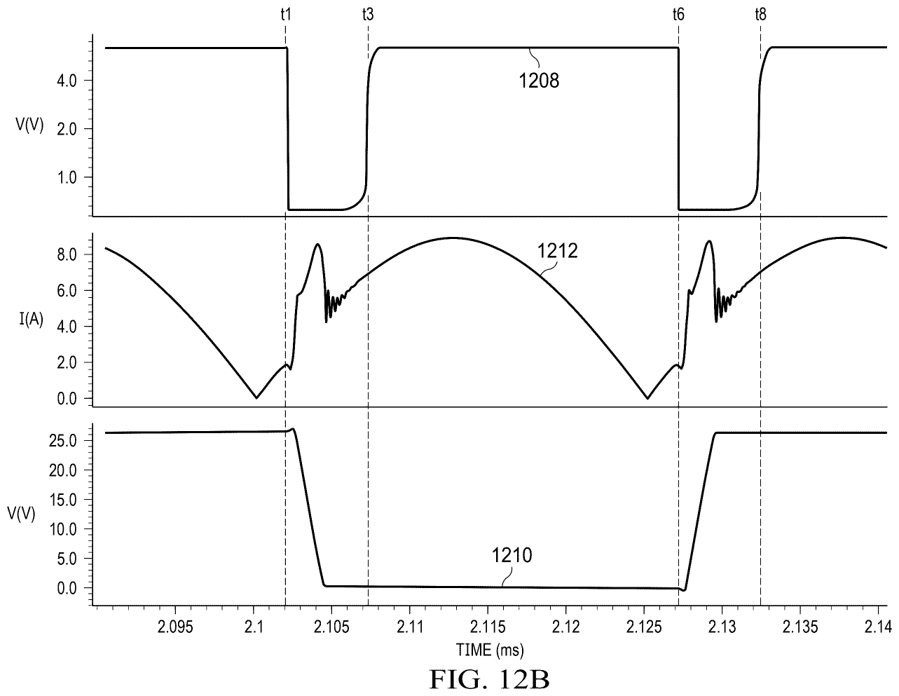

FIG. 12A and FIG. 12B include graphs illustrating example operations of overcurrent threshold generation circuit 602 of FIGS. 6-11. FIGS. 12A and 12B include graphs 1202, 1204, 1206, 1208, 1210, and 1212. Graph 1202 illustrates an example variation of clamp detection signal 734 with time. Graph 1204 illustrates an example variation of slew rate signal 732 with time. Graph 1206 illustrates an example variation of control signal 736 with time. Graph 1208 illustrates an example variation of control signal 738 with time. Graph 1210 illustrates an example variation of the VN voltage with time. Graph 1212 illustrates an example variation of the current provided by the power stage PS1 with time.

Referring to FIGS. 12A and 12B, slew rate signal 732 is at the high logic state when the VN voltage is at the clamped state, such as before time t0, between times t4 and t5, and after time t9, because there is no or very little changes in the VN voltage. Slew rate signal 732 is at the low logic state between times t0 and t4 and between times t5 and t9, while the transition of the VN voltage between V1 (e.g., 25V) and V0 (e.g., 0V) that leads to huge current spikes is only between times t1 and t2 and between t6 and t7. Accordingly, clamp detection signal 734 and slew rate signal 732 both a low logic state only during the transition intervals between t1 and t2 and between t6 and t7, and control signal 736 at the output of logic gate 706 has a low logic state only during those transition intervals in FIGS. 12A and 12B.

Also, referring to graph 1208, control signal 738 (from inverter 738) transitions from the low logic state to the high logic state at times t1 and t6 responsive to control signal 736 transitions from the low logic state to the high logic state, and the overcurrent threshold increases to an elevated level at times t1 and t6. The overcurrent threshold stays at the elevated level beyond times t2 and t7 when control signal 738 transitions back to the low logic state, due to the slow pull-down configuration shown in FIG. 7. Referring to FIG. 12B, control signal 738 transitions back to the low logic state at times t3 and t8. As described above, such arrangements allow the overcurrent threshold to remain at the elevated level to avoid the parasitic ringing after the transition interval ends false triggering the overcurrent protection circuits.

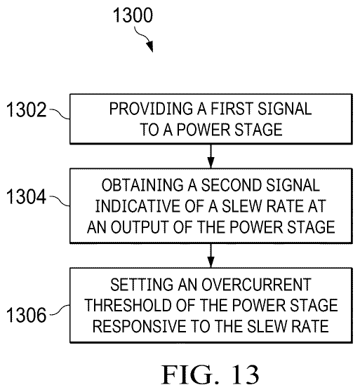

FIG. 13 illustrates a flowchart of an example method 1300 of operating a power stage. Method 1300 can be performed by a system including overcurrent threshold generation circuit 602, such as audio driver circuit 300 and/or audio signal generation circuit 306

In operation 1302, a system (e.g., audio driver circuit 300, audio signal generation circuit 306) can provide a first signal to a power stage, such as the power stage PS1. The first signal can be provided by audio driver circuit 300 responsive to audio signals from signal generation circuit 306, or can be audio signals provided by signal generation circuit 306 responsive to sequence of digital signals 1104.

In operation 1304, the overcurrent threshold generation circuit can obtain a second signal indicative of (or predictive of) a slew rate at an output of the power stage. As described above, the second signal can be obtained based on measuring a slew rate of the audio signals at the inputs of audio driver circuit 300, a slew rate of the control signal CS1 at the output of amplifier 308, or the VN voltage at the output of the power stage PS1. As described above, obtaining the second signal by measuring a slew rate of the audio signals at the inputs of audio driver circuit 300 or the control signal CS1 can relax the bandwidth requirement of the overcurrent threshold generation circuit in setting/adjusting the overcurrent threshold.

In operation 1306, the overcurrent threshold generation circuit can set the overcurrent threshold of the power stage responsive to the slew rate. As described above, the overcurrent threshold generation circuit can increase the overcurrent threshold from a default value to an elevated value if the slew rate exceeds a threshold, to avoid the current spikes during the transition intervals of the VN voltage falsely triggering the overcurrent protection circuits. In some examples, the overcurrent threshold generation circuit can increase the overcurrent threshold from the default value to different elevated values based on which range the slew rate is in. In some examples, the overcurrent threshold generation circuit can set the overcurrent threshold proportionally to the slew rate. Also, the overcurrent threshold generation can maintain the elevated overcurrent threshold for an extended time after the transition interval ends to cover parasitic ringing in the power stage current.

In some examples, the overcurrent threshold generation circuit determines whether the power stage operates in the linear region or in the saturation region, and set the overcurrent threshold responsive to the slew rate if the power stage operates in the linear region. If the power stage operates in the saturation region, the overcurrent threshold generation circuit can maintain the overcurrent threshold at its default value. The overcurrent threshold generation circuit can determine whether the power stage operates in the linear region or in the saturation region by, for example, comparing a voltage at the input of the power stage against a threshold.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used, such as laterally-diffused metal-oxide semiconductor (LDMOS) FETs) and bipolar junction transistors (BJTs). Furthermore, the devices may be implemented in/over a silicon substrate (Si), a silicon carbide substrate (SiC), a gallium nitride substrate (GaN) or a gallium arsenide substrate (GaAs).

References herein to a field effect transistor (FET) being “ON” means that the conduction channel of the FET is present and drain current may flow through the FET. References herein to a FET being “OFF” means that the conduction channel is not present and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described embodiments and examples, and other embodiments and examples are possible, within the scope of the claims, such as the examples herein below.

What is claimed is:

1. An apparatus comprising:
an amplifier having an amplifier input and an amplifier output;
a power stage having a power stage input and a power stage output, the power stage input coupled to the amplifier output; and
an overcurrent protection circuit coupled to the power stage, the overcurrent protection circuit having an overcurrent threshold control input coupled to the amplifier.

2. The apparatus of claim 1, further comprising a threshold generation circuit having a control input and a threshold output, the control input coupled to the amplifier, the threshold output coupled to the overcurrent threshold control input, and the threshold generation circuit configured to:
receive a signal indicative of a slew rate at the power stage output; and
provide an overcurrent threshold at the threshold output responsive to the slew rate.

3. The apparatus of claim 2, wherein the control input is coupled to the amplifier input.

4. The apparatus of claim 2, wherein the control input is coupled to the amplifier output.

5. The apparatus of claim 2, wherein the control input is coupled to the power stage output.

6. The apparatus of claim 2, wherein the threshold generation circuit is configured to:
responsive to the slew rate exceeding a slew rate threshold, provide a first overcurrent threshold at the threshold output; and
responsive to the slew rate being equal to or below the slew rate threshold, provide a second overcurrent threshold at the threshold output, the second overcurrent threshold being lower than the first overcurrent threshold.

7. The apparatus of claim 2, wherein the threshold generation circuit is configured to:
responsive to the slew rate being within a first range, provide a first overcurrent threshold at the threshold output;
responsive to the slew rate being within a second range, provide a second overcurrent threshold at the threshold output; and
responsive to the slew rate being within a third range, provide a third overcurrent threshold at the threshold output.

8. The apparatus of claim 2, wherein the threshold generation circuit is configured to provide the overcurrent threshold that is proportional to the slew rate.

9. The apparatus of claim 2, wherein the threshold generation circuit is configured to:
set the overcurrent threshold to a first value;
responsive to the signal, increase the overcurrent threshold from the first value to a second value; and
after a pre-determined period elapses from the increase, reduce the overcurrent threshold from the second value back to the first value.

10. The apparatus of claim 2, wherein the threshold generation circuit includes:
a pulse generator having an output coupled to a first resistor and a first capacitor;
a current sensor having a sensor input and a sensor output, the sensor input coupled to the first resistor, and the sensor output coupled to a second resistor;
a second capacitor coupled between the control input and an input of an absolute value circuit, the absolute value circuit having an output coupled to a third resistor; and
a comparator having inputs coupled to the sensor output and the output of the absolute value circuit; and
a controllable voltage source coupled between a power supply and the threshold output, the controllable voltage source having a control input coupled to the output of the comparator.

11. The apparatus of claim 2, wherein the control input is a first control input, the threshold generation circuit has a second control input coupled to the amplifier output, and the threshold generation circuit configured to, responsive to a voltage at the amplifier output being below a voltage threshold, provide the overcurrent threshold at the threshold output responsive to the slew rate.

12. The apparatus of claim 2, wherein the power stage is a first power stage, the power stage input is a first power stage input, the power stage output is a first power stage output;
wherein the amplifier is a linear amplifier, the amplifier input is a first amplifier input coupled to a first audio input, the amplifier has a second amplifier input coupled to a second audio input; and
wherein the apparatus further comprises:
a low pass filter having a first filter input, a second filter input, a first filter output, and a second filter output;
a modulator circuit having a first modulator input, a second modulator input, a third modulator input, and a modulator output, the first modulator input coupled to the first filter output, the second modulator input coupled to the second filter output, the third modulator input coupled to the amplifier output; and
a second power stage having a second power stage input and a second power stage output, the second power stage input coupled to the modulator output.

13. The apparatus of claim 12, further comprising:
a first resistor coupled between the first audio input and the first filter input;
a second resistor coupled between the second audio input and the second filter input;
a third resistor coupled between the first audio input and the second power stage output; and
a fourth resistor coupled between the second audio input and the first power stage output.

14. The apparatus of claim 12, wherein the first power stage output is coupled to a first audio output, and the apparatus further comprises:
a first capacitor coupled between the first audio output and a ground terminal;
a second capacitor coupled between the first audio output and a second audio output; and
an inductor coupled between the second power stage output and the second audio output.

15. The apparatus of claim 12, further comprising an audio signal generation circuit having outputs coupled to the first and second audio inputs, wherein the threshold generation circuit is part of the audio signal generation circuit.

16. An apparatus comprising:
an amplifier having an amplifier input and an amplifier output;
a first power stage having a first power stage input and a first power stage output, the first power stage input coupled to the amplifier output;
an overcurrent protection circuit coupled to the first power stage, the overcurrent protection circuit having an overcurrent threshold control input coupled to the amplifier;
a modulator having a modulator input and a modulator output, the modulator input coupled to the amplifier input; and
a second power stage having a second power stage input and a second power stage output, the second power stage input coupled to the modulator output.

17. The apparatus of claim 16, further comprising:
a first capacitor coupled between the first power stage output and a ground terminal; and
a second capacitor and an inductor coupled between the first power stage output and the second power stage output.

18. A method comprising:
providing a first signal to a power stage;
obtaining a second signal indicative of a slew rate at an output of the power stage; and
setting an overcurrent threshold of the power stage responsive to the slew rate.

19. The method of claim 18, further comprising:
responsive to the slew rate being above a slew rate reference, increasing the overcurrent threshold from a first value to a second value; and
after a pre-determined duration elapses from the increase, decreasing the overcurrent threshold from the second value back to the first value.

20. The method of claim 18, further comprising:
responsive to a voltage at an input of the power stage being below a voltage threshold, setting the overcurrent threshold responsive to the slew rate.
